(19) United States
(12) Patent Application Publication
(10) Pub. No.: US 2011/0298111 A1
(43) Pub. Date: Dec. 8, 2011

(54) SEMICONDUCTOR PACKAGE AND MANUFACTRING METHOD THEREOF

(75) Inventor: Jung Woo KIM, Hwaseong (KR)

(73) Assignee: SAMSUNG ELECTRO-MECHANICS CO., LTD., Gyunggi-do (KR)

(21) Appl. No.: 13/012,214

(22) Filed: Jan. 24, 2011

(30) Foreign Application Priority Data
Jun. 8, 2010 (KR) 10-2010-0054006

(51) Int. Cl. H01L 23/552; H01L 21/50

(52) U.S. Cl. 257/660; 438/113; 257/E23.114; 257/E21.499

(57) ABSTRACT

There is provided a semiconductor package capable of protecting a passive element, a semiconductor chip, or the like included in the package from external force and having enhanced Electro Magnetic Interference (EMI) and Electro Magnetic Susceptibility (EMS) characteristics and a manufacturing method thereof. The semiconductor package includes a substrate having at least one cavity formed in a side surface thereof and an electrode provided within the cavity; at least one electronic component mounted on a surface of the substrate; a mold part sealing the electronic component and having insulating properties; and a shield part attached to the mold part to cover an outer surface of the mold part, electrically connected to the electrode provided within the cavity, and having conductive properties.

### CROSS-REFERENCE TO RELATED APPLICATIONS

This application claims the priority of Korean Patent Application No. 10-2010-0054006 filed on Jun. 8, 2010, in the Korean Intellectual Property Office, the disclosure of which is incorporated herein by reference.

### BACKGROUND OF THE INVENTION

1. Field of the Invention

The present invention relates to a semiconductor package and a manufacturing method thereof, and more particularly, to a semiconductor package capable of protecting a passive element, a semiconductor chip, or the like included in the package from external impacts and having enhanced Electro Magnetic Interference (EMI) and Electro Magnetic Susceptibility (EMS) characteristics and a manufacturing method thereof.

2. Description of the Related Art

In recent years, demand for portable devices in the electronic device market has rapidly increased. In order to satisfy the demand therefor, electronic components mounted thereon are required to be small and lightweight.

In order to manufacture small and lightweight electronic components, a technique aimed at reducing the individual sizes of mounting components, a system on chip (SOC) technique aimed at integrating a plurality of individual devices into a single chip, and a system in package (SIP) technique aimed at integrating a plurality of individual devices into a single package are required.

Particularly, a high frequency semiconductor package using a high frequency signal, such as a portable TV module (DMB or DVB) or a network module, is required to have a reduction in the size thereof and to include a structure for shielding electromagnetic waves in order to have enhanced Electro Magnetic Interference (EMI) and Electro Magnetic Susceptibility (EMS) characteristics.

As a structure for shielding electromagnetic waves in a general high frequency semiconductor package, a metallic case structure covering individual devices mounded on a substrate is well-known. A metallic case applied to the general high frequency semiconductor package is intended to cover all of the individual devices so as to protect the individual devices from external impacts and achieve the shielding of electromagnetic waves through an electrical connection with a ground.

However, this metallic case is not strong enough to endure external impacts. Also, the metallic case is difficult to closely attach to the substrate, so it is not entirely effective in the shielding of electromagnetic waves.

### SUMMARY OF THE INVENTION

An aspect of the present invention provides a semiconductor package protecting individual devices included therein from external impacts and having a structure for shielding electromagnetic waves with enhanced Electro Magnetic Interference (EMI) and Electro Magnetic Susceptibility (EMS) characteristics and a manufacturing method thereof.

According to an aspect of the present invention, there is provided a semiconductor package including: a substrate having at least one cavity formed in a side surface thereof and an electrode provided within the cavity; at least one electronic component mounted on a surface of the substrate; a mold part sealing the electronic component and having insulating properties; and a shield part attached to the mold part to cover an outer surface of the mold part, electrically connected to the electrode provided within the cavity, and having conductive properties.

The shield part may be provided to extend along the side surface of the substrate.

The electrode may be provided on at least one surface of the cavity.

The electrode may be formed by filling the cavity with a conductive material.

The cavity may be elongated in the side surface of the substrate in a lengthwise direction.

According to another aspect of the present invention, there is provided a method of manufacturing a semiconductor package, the method including: preparing a substrate having at least one cavity and an electrode provided within the cavity; mounting an electronic component on an upper surface of the substrate; forming a mold part having insulating properties to seal the electronic component; and forming a shield part on an outer surface of the mold part, the shield part being electrically connected to the electrode provided within the cavity and having conductive properties.

The substrate may have the cavity formed in at least one side surface thereof.

The shield part may be formed to extend up to the side surface of the substrate.

The substrate may be shaped as a strip including a plurality of individual semiconductor package areas.

The substrate may have the cavity formed in the inside thereof along a boundary dividing the individual semiconductor package areas.

The electronic component may be mounted on each of the individual semiconductor package areas.

The mold part may be integrally formed to seal all the individual semiconductor package areas.

The forming of the shield part may include dividing the substrate having the mold part formed thereon into individual semiconductor packages by cutting the substrate according to the individual semiconductor package areas, and forming the shield part on each of the individual semiconductor packages.

The dividing of the substrate into the individual semiconductor packages may cause the cavity to be exposed through the side surface of the substrate being cut.

The forming of the shield part on each of the individual semiconductor packages may be performed by spray coating.

The forming of the shield part may include a first cutting process cutting the substrate having the mold part formed thereon according to the individual semiconductor package areas only up to a position where the cavity is formed; forming the shield part on the substrate subjected to the first cutting process; and a second cutting process completely cutting the substrate having the shield formed thereon.

The forming of the shield part on the substrate subjected to the first cutting process may include forming the shield part on the outer surface of the mold part and in the cavity exposed through the first cutting process.

The second cutting process may be performed to cause a cut surface of the substrate and a vertical outer surface of the shield part to be positioned on different planes.

The forming of the shield part on the substrate subjected to the first cutting process may be performed by any one of spray coating or screen printing.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view illustrating a semiconductor package according to an exemplary embodiment of the present invention;

FIG. 2 is a perspective view illustrating the semiconductor package of FIG. 1;

FIG. 3 is a cross-sectional view illustrating a semiconductor package according to another exemplary embodiment of the present invention;

FIGS. 4A through 4E are cross-sectional views illustrating a method of manufacturing a semiconductor package according to an exemplary embodiment of the present invention;

FIGS. 5A through 5G are cross-sectional views illustrating a method of manufacturing a semiconductor package according to another exemplary embodiment of the present invention;

FIGS. 6A through 6E are cross-sectional views illustrating a method of manufacturing a substrate according to an exemplary embodiment of the present invention; and

FIGS. 7A through 7G are cross-sectional views illustrating a method of manufacturing a substrate according to another exemplary embodiment of the present invention.

### DETAILED DESCRIPTION OF THE PREFERRED EMBODIMENT

Prior to a detailed description of the present invention, the terms or words, which are used in the specification and claims to be described below, should not be construed as having typical or dictionary meanings. The terms or words should be construed in conformity with the technical idea of the present invention on the basis of the principle that the inventor(s) can appropriately define terms in order to describe his or her invention in the best way. Embodiments described in the specification and structures illustrated in drawings are merely exemplary embodiments of the present invention. Thus, it is intended that the present invention covers the entirety of modifications and variations of this invention, provided they fall within the scope of their equivalents at the time of filing this application.

Exemplary embodiments of the present invention will be described in detail with reference to the accompanying drawings. The same reference numerals will be used throughout to designate the same or like elements in the accompanying drawings. Moreover, detailed descriptions related to well-known functions or configurations will be ruled out in order not to unnecessarily obscure the subject matter of the present invention. In the drawings, the shapes and dimensions of some elements may be exaggerated, omitted or schematically illustrated. Also, the size of each element does not entirely reflect an actual size.

Exemplary embodiments of the present invention will now be described in detail with reference to the accompanying drawings.

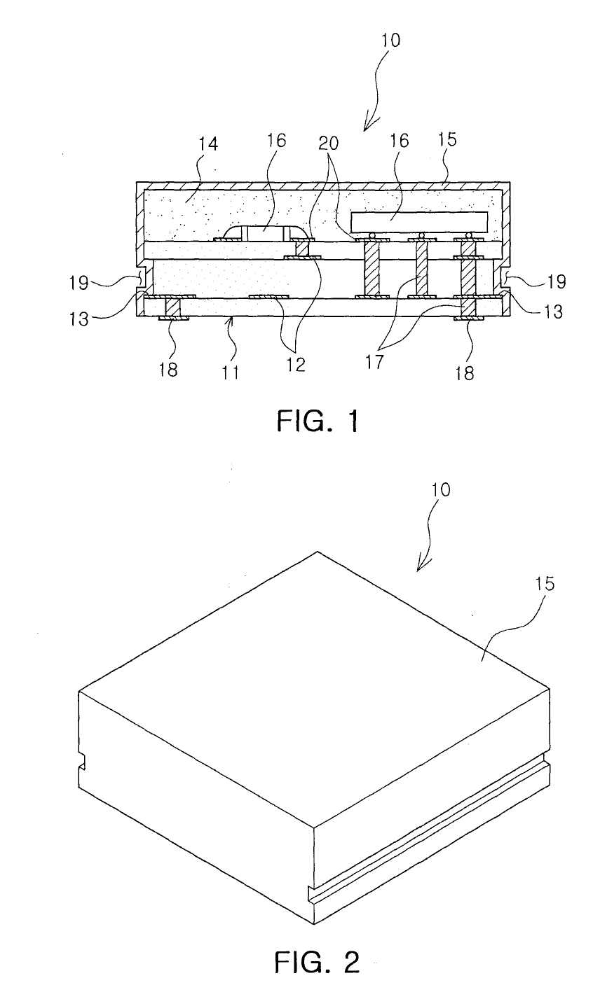

FIG. 1 is a cross-sectional view illustrating a semiconductor package according to an exemplary embodiment of the invention, and FIG. 2 is a perspective view illustrating the semiconductor package of FIG. 1.

As shown in FIGS. 1 and 2, a semiconductor package 10 according to an exemplary embodiment of the invention includes a substrate 11, an electronic component 16, a mold part 14, and a shield part 15.

The substrate 11 has at least one or more electronic components 16 mounted on the upper surface thereof. The substrate 11 may be various types of substrates known in the art to which the invention pertains. For example, a ceramic substrate, a printed circuit board (PCB), a flexible substrate, or the like may be used therefor.

The substrate 11 may have electrodes 20 and circuit patterns (not shown) formed on the upper surface thereof, in which the electrodes 20 are used for the mounting of the electronic components 16 and the circuit patterns make electrical connections between the electrodes 20. Also, the substrate 11 may be a multi-layered substrate including a plurality of layers, in which a circuit pattern 12 may be formed to make electrical connections between the individual layers.

According to the present embodiment, a cavity 19 is formed in at least one or more side surfaces of the substrate 11. The cavity 19 may have the form of a recess. As shown in FIG. 2, the cavity 19 may be continuously elongated in the side surface of the substrate 11 in a lengthwise direction thereof. However, the invention is not limited thereto. The cavity 19 may have various forms, in that a plurality of cavities may be formed discontinuously in the side surfaces of the substrate 11.

FIGS. 1 and 2 show the case in which the cavity 19 is formed in each of two side surfaces of the substrate 11. However, the invention is not limited thereto, and the cavity 19 may be formed in only a single side surface of the substrate 11 or in all the four side surfaces thereof.

A ground electrode 13 is formed in the inside of the cavity 19. The ground electrode 13 may be electrically connected to the circuit pattern 12 formed inside the substrate 11 and also be electrically connected to an external connection terminal 18. Also, the ground electrode 13 extends up to the side surface of the substrate 11, and the end thereof is exposed to the side surface of the substrate 11.

With reference to FIG. 1, the ground electrode 13 is formed of a metallic layer (i.e., part of the circuit pattern) on the lower surface of the cavity 19; however, the invention is not limited thereto. That is, the ground electrode 13 may be formed on at least any one of the surfaces (e.g., a vertical surface) forming the inside of the cavity 19. Also, the cavity 19 may be fully filled with a conductive material such that the ground electrode 13 may be formed to fill the entirety of the cavity 19. The form of the ground electrode 13 will be provided through a detailed description of a method of manufacturing a substrate to be described below.

Also, the substrate 11 according to this embodiment may include the electrodes 20 formed on the upper surface thereof, the external connection terminals 18 electrically connected to the circuit patterns 12 formed inside the substrate 11, and conductive via holes 17 making electrical connections among the electrodes 20, the circuit patterns 12 and the external connection terminals 18. Also, the substrate 11 may further include a separate cavity (not shown) for mounting an electronic component inside the substrate 11.

The mold part 14 is formed to seal the electronic components 16 mounted on the substrate 11 so that the mold part 14 prevents electrical short circuiting between the electronic components 16 and protects the electronic components 16 from external impacts by fixing the electronic components 16 enclosed thereby. The mold part 14 may be formed of an insulating material including a resin material such as epoxy resin.

The shield part 15 is closely attached to the mold part 14 so that the shield part 15 covers the outer surface of the mold part 14. The shield part 15 should be grounded so as to block electromagnetic waves. To enable this, the shield part 15 of the semiconductor package 10 according to this embodiment is electrically connected to the ground electrode 13. More particularly, the shield part 15 is basically formed along the outer surface of the mole part 14. The shield part 15 may be formed to further extend up to the side surfaces of the substrate 11 to be electrically connected to the ground electrode 13 disposed within the cavity 19 exposed to the side surfaces of the substrate 11.

This shield part 15 may be formed of various conductive materials. For example, the shield part 15 may be formed of a resin material containing conductive powder or of a metallic thin film. In the case of forming a metallic thin film, various techniques such as sputtering, vapor deposition, electroplating, or electroless plating may be used therefor. Particularly, the shield part 15 may be a metallic thin film formed by spray coating. The spray coating has advantages in the formation of a uniform coating film and a reduction of manufacturing costs as compared with other techniques. However, the invention is not limited thereto. A metallic thin film formed by screen printing may be used as the shield part 15.

As described above, the semiconductor package 10 according to the present invention has the mold part 14 and the shield part 15 formed along the outer surface of the mold part 14 so that the mold part 14 may protect the electronic component 16 mounted on the substrate 11 from external force, and the shield part 15 may increase the effect of shielding electromagnetic waves. Also, in order to ground the shield part 15 for shielding electromagnetic waves, the ground electrode 13 within the cavity 19 formed in the side surface of the substrate 11 may be used to thereby facilitate the grounding of the shield part 15.

Also, since the cavity 19 formed inside the substrate 11 provides a wider contact area for electrical connection between the shield part 15 and the ground electrode 13, electrical reliability therebetween may be achieved.

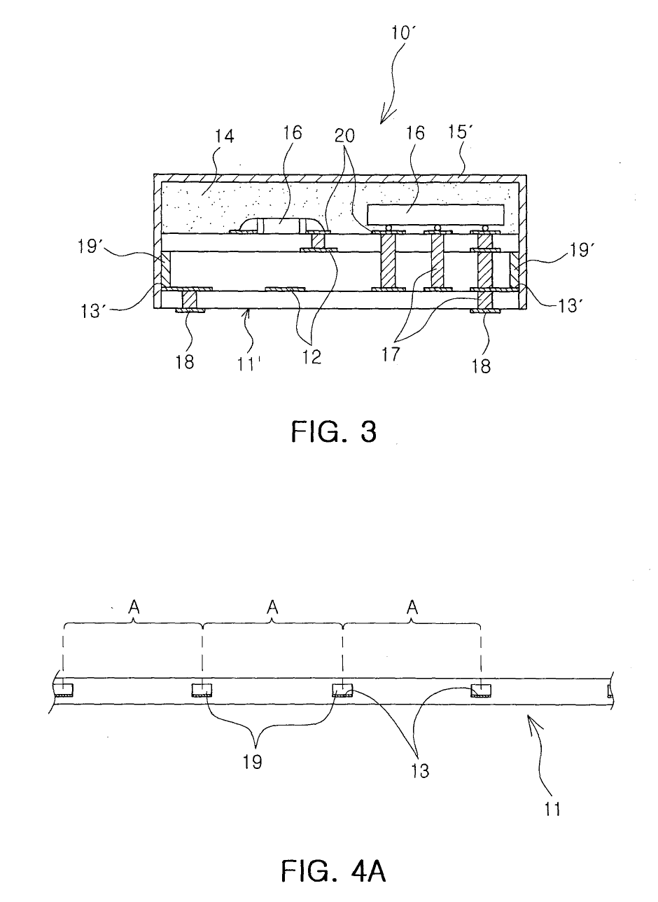

FIG. 3 is a cross-sectional view illustrating a semiconductor package according to another exemplary embodiment of the invention. A semiconductor package 10′ according to this embodiment has a similar structure as compared with the semiconductor package 10 of FIG. 1, with the exception of a difference in the form of a ground electrode 13′ formed inside a cavity 19′. In the semiconductor package 10′, the ground electrode 13′ is formed to fill the entirety of the cavity 19′. In this case, since the outer surface of the ground electrode 13′ and the side surface of the substrate 11′ are positioned on the same plane, electrical connection between a shield part 15′ and the ground electrode 13′ may be further facilitated.

That is, the semiconductor package 10 and 10′ according to the embodiments of the invention may have various forms in terms of the structure of the cavity 19 and 19′ and the ground electrode 13 and 13′ formed inside the cavity 19 and 19′.

Meanwhile, after a plurality of packages are simultaneously formed on a substrate having a strip shape, a dicing process is performed to thereby form individual semiconductor packages. Hereinafter, a method of manufacturing the above-described semiconductor package will be described. Meanwhile, since the manufacturing method to be described below is in relation to the method of manufacturing the above-described semiconductor package, a detailed description of the same elements will be omitted. Also, the same reference numerals will be used to designate the same elements.

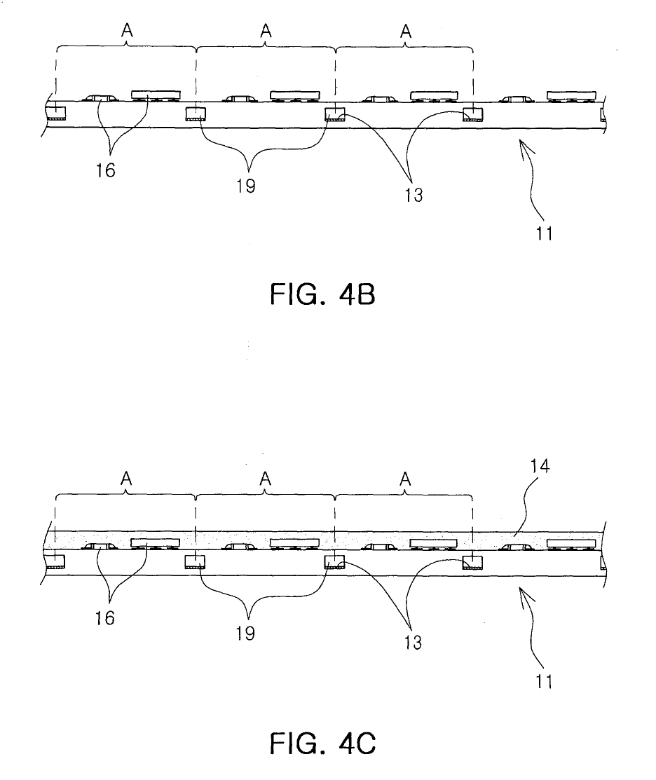

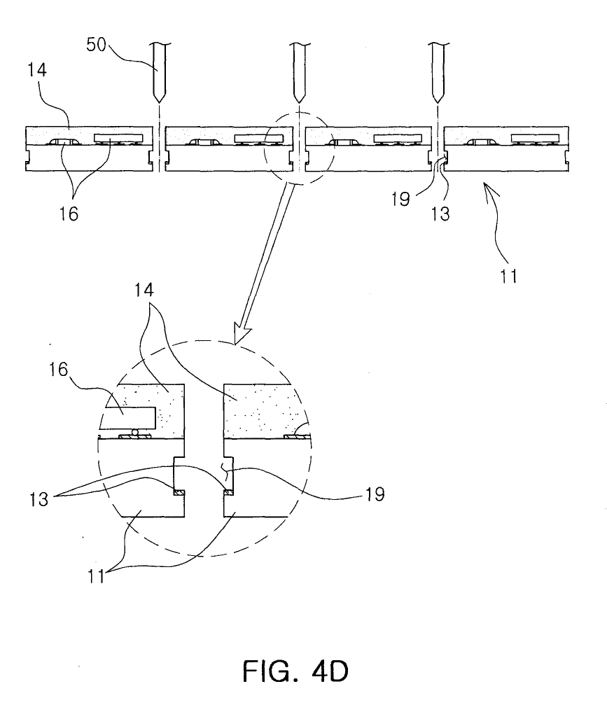

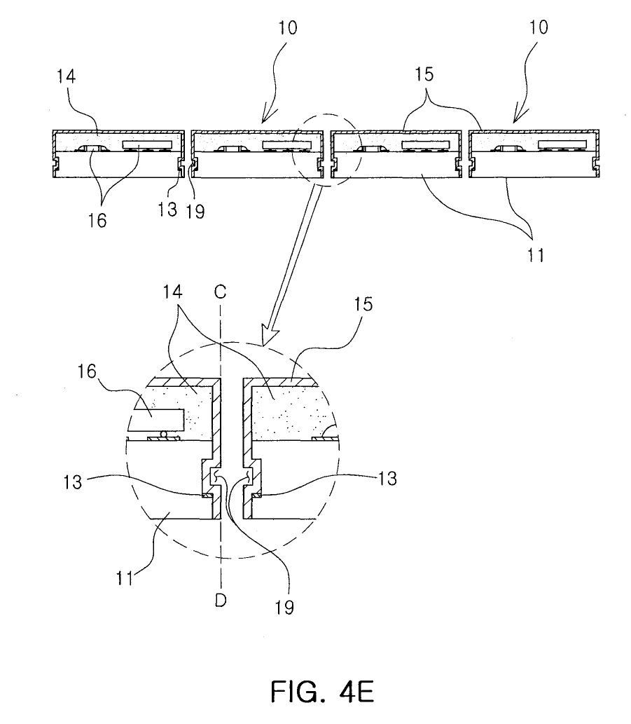

FIGS. 4A through 4E are cross-sectional views illustrating subsequent manufacturing processes of a semiconductor package according to an exemplary embodiment of the invention.

With reference to FIG. 4A, in the method of manufacturing the semiconductor package according to the embodiment of the invention, the substrate 11 is firstly prepared in operation S10.

Meanwhile, the substrate 11 according to this embodiment has a strip shape (hereinafter, also referred to as the “strip substrate”). The strip substrate 11 is intended to manufacture a plurality of individual semiconductor packages 10 simultaneously. The strip substrate 11 has a plurality of individual semiconductor package areas A divided thereon such that the semiconductor packages 10 are manufactured according to the plurality of individual semiconductor package areas A.

Also, the substrate 11 according to the present embodiment is a multilayered circuit board including a plurality of layers, in which circuit patterns may be formed to make electrical connections between the individual layers. More specifically, the substrate 11 may have the circuit patterns 12, the external connection terminals 18, the electrodes 20 and the via holes 17 of FIG. 1 formed therein.

The substrate 11 according to this embodiment has the cavities 19 formed therein. In the case of the substrate 11 of FIG. 1, the cavity 19 is formed in the side surface of the substrate 11. This is because the strip substrate 11 of FIG. 4A is subjected to a cutting process according to the individual semiconductor package areas A in operations S16 and S25 to be described below and the cutting thereof causes the cavity 19 to be exposed through the side surface of the substrate 11. With regard to the manufacturing of the semiconductor package 10 according to this embodiment, the strip substrate 11 having the cavity 19 in the inside thereof as shown in FIG. 4A, rather than in the side surface thereof, is used.

This strip substrate 11 is divided according to the individual semiconductor package areas A, and the cavity 19 is formed inside the substrate 11 along a boundary between adjacent semiconductor package areas A. Accordingly, when the substrate 11 is cut along the boundary in operations S16 and S25 to be described below, the cavity 19 is exposed to the side surface of the substrate 11.

A method of manufacturing the substrate 11 according to the present invention will now be described below.

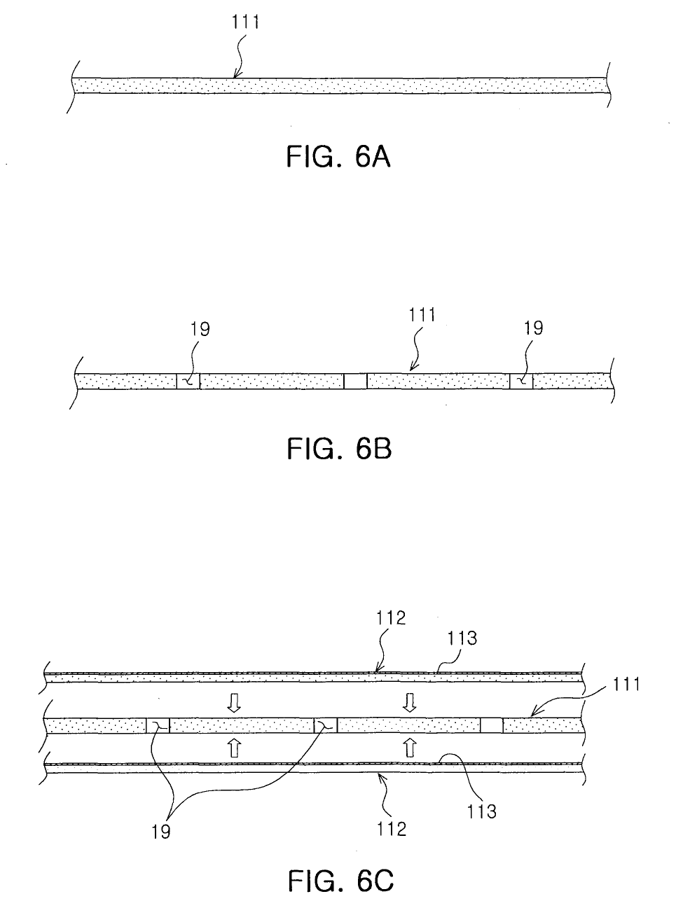

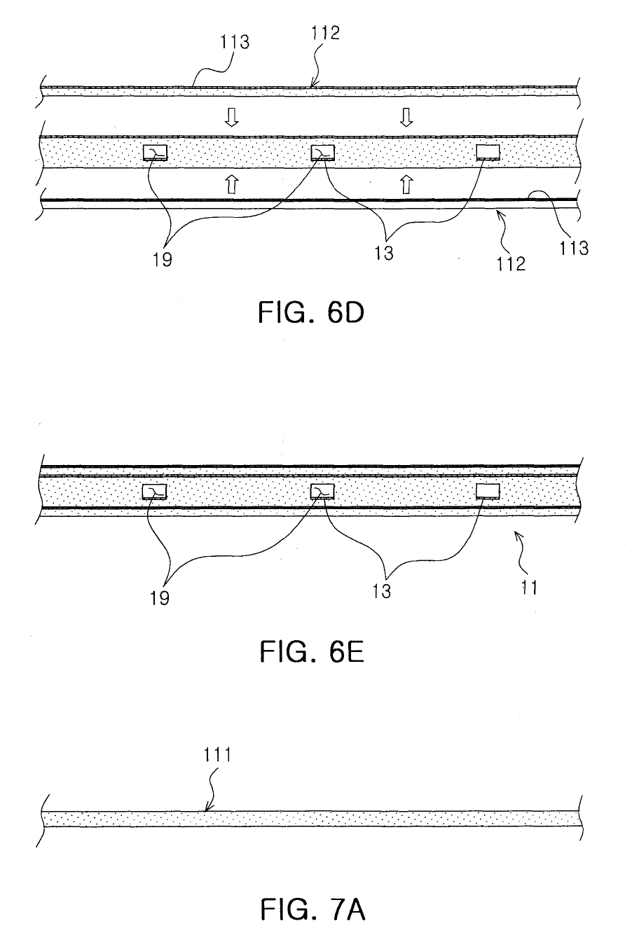

FIGS. 6A through 6E are cross-sectional views illustrating a method of manufacturing a substrate according to an exemplary embodiment of the invention.

Firstly, as shown in FIG. 6A, a core layer 111 is prepared.

As shown in FIG. 6B, parts of the core layer 111 are removed at uniform distances to form the cavities 19. As described above, the substrate 11 is provided in a strip shape. Accordingly, the cavities 19 are formed to have uniform distances therebetween along boundaries between individual semiconductor package areas (see “A” of FIG. 4A).

Next, as shown in FIG. 6C, at least one or more resin layers 112 are stacked on the upper and lower parts of the core layer 111. The resin layer 112 may be formed of prepreg, but is not limited thereto. Also, the resin layer 112 may have a conductive layer 113 formed on one or both surfaces thereof. According to the present embodiment, the resin layer 112 has the conductive layer 113 formed only on the upper surface thereof. Accordingly, the conductive layer 113 of the resin layer 112 attached to the lower surface of the core layer 111 is exposed to the insides of the cavities 19 of the core layer 111. The conductive layer 113 exposed to the insides of the cavities 19 of the core layer 111 is to be used as the ground electrode 13.

In this manner, when the resin layers 112 are stacked on the upper and lower parts of the core layer 111, they are pressed to integrate the resin layers 112 with the core layer 111, thereby forming the substrate as shown in the middle of FIG. 6D.

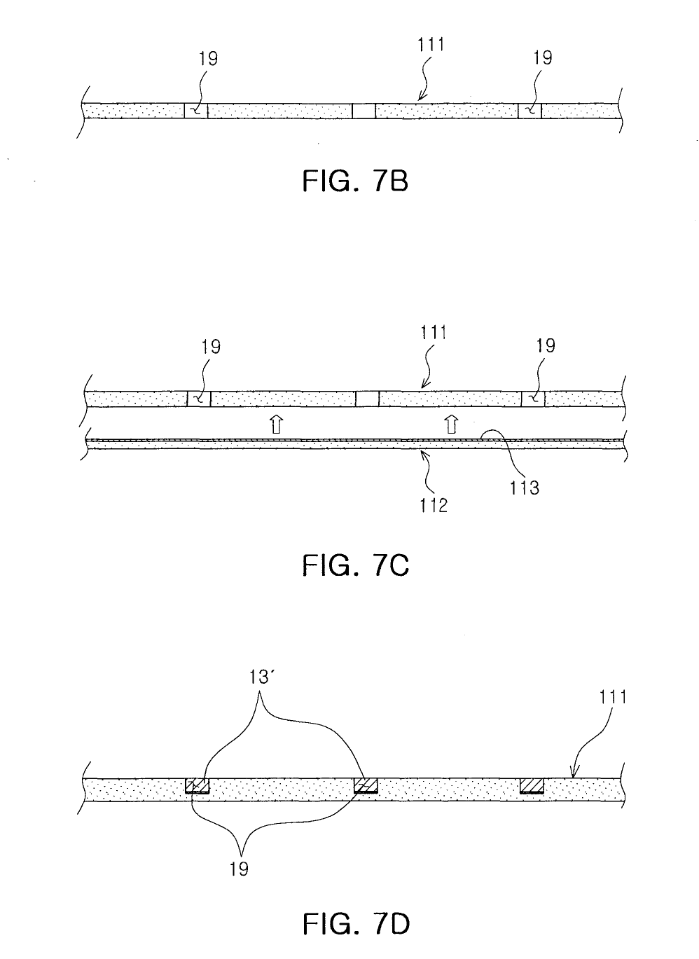

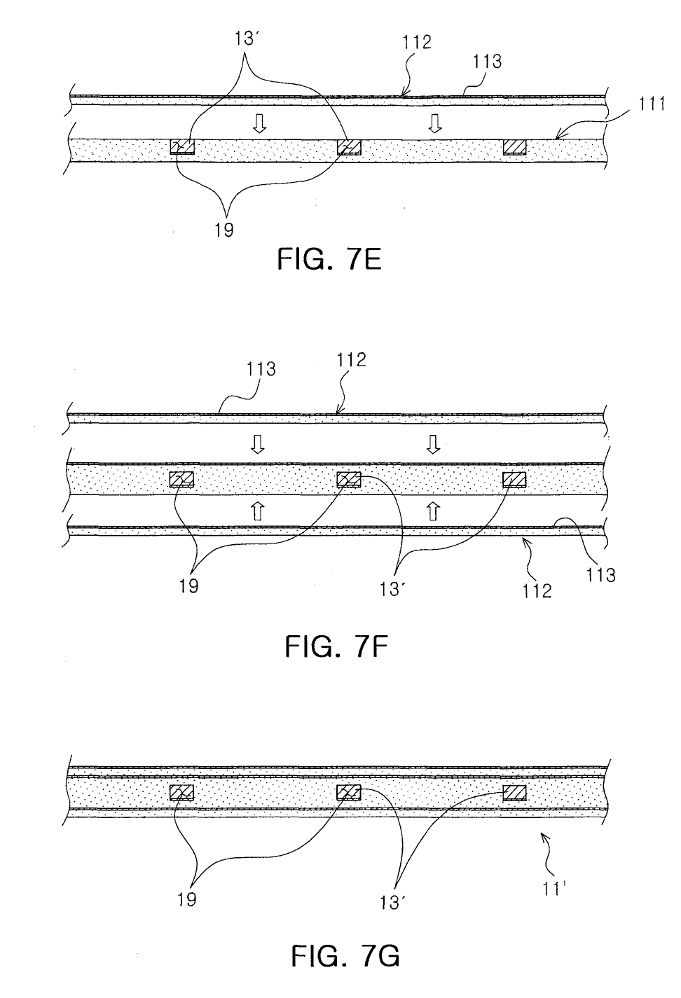

Meanwhile, for a more detailed understanding, the conductive layer 113 of the resin layer 112 stacked on the lower surface of the core layer 111 is depicted in FIG. 6D in a manner such that only the parts of the conductive layer 113 exposed to the insides of the cavities 19 are depicted as the ground electrodes 13 and the other parts thereof are omitted. This is applied to the exemplary embodiment of FIGS. 7A through 7G to be described below in the same manner.

Then, further resin layers 112 are stacked and pressed as shown in FIG. 6D, and accordingly, the multilayered circuit board 11 is formed as shown in FIG. 6E.

Here, before the resin layers 112 are stacked on the core layer 111, circuit patterns may be formed on the conductive layer 113 formed on each of the resin layers 112.

Also, the substrate 11 manufactured according to the embodiment of FIGS. 6A through 6E includes the two resin layers 112 stacked on each of the both surfaces of the core layer 111. However, the invention is not limited thereto. The substrate 11 may have various forms such that only a single resin layer is stacked on the lower surface of the core layer 111 or two or more resin layers are stacked on the both surfaces of the core layer 111.

In the method of manufacturing the substrate according to the present embodiment as described above, the ground electrode 13 is formed by the use of the conductive layer 113 formed on the resin layer 112. Accordingly, as shown in the semiconductor package 10 of FIG. 1, the ground electrode 13 may be formed on the lower surface of the cavity 19.

FIGS. 7A through 7G are cross-sectional views illustrating a method of manufacturing a substrate according to another exemplary embodiment of the invention.

With reference to FIGS. 7A through 7G, the manufacturing method according to this embodiment is to manufacture the substrate 11′ employed in the semiconductor package 10′ of FIG. 3. The formations of the core layer 111 and the cavities 19 in FIGS. 7A and 7B are performed in the same manner as described in FIGS. 6A and 6B of the aforementioned embodiment. Accordingly, a detailed description of the same processes is omitted, and a detailed description of subsequent processes is now provided.

With reference to FIG. 7C, the resin layer 112 is attached to the lower surface of the core layer 111. In this manner, the cavity 19 of the core layer 111 has the form of a recess, rather than the form of a through-hole.

Subsequently, as shown in FIG. 7D, the cavity 19 formed in the core layer 111 is filled with a conductive material 13′ in a paste state. Here, the conductive material 13′ is to be used as the ground electrode 13′. For this reason, the same reference numeral is used therefor. Such a conductive material 13′ may adopt Cu or the like.

After the cavity 19 is filled with the conductive material 13′ and a hardening process is then performed thereupon, the resin layer 112 is stacked on the upper surface of the core layer 111 as shown in FIG. 7E.

Thereafter, the processes of FIGS. 7F and 7G are performed in the same manner as described in the processes of FIGS. 6D and 6E. That is, the substrate 11′ according to the present embodiment is manufactured by repeatedly performing the stacking of the resin layers 112 on the upper and lower surfaces of the core layer 111 and the pressing thereof.

In the method of manufacturing the substrate according to this embodiment as described above, the ground electrode (see “13′” of FIG. 3) is formed of the conductive material 13′ filling the inside of the cavity 19. Accordingly, like the semiconductor package 10′ of FIG. 3, the ground electrode 13′ is formed by filling the entirety of the cavity 19.

A method of manufacturing a substrate is not limited to the above-described two embodiments of the invention. That is, when the substrate is manufactured, the vertical surface (i.e., surface of a wall of the core layer) of the cavity (see “19” of FIG. 1) may be coated with a conductive material to thereby be used as a ground electrode. In this case, the ground electrode is formed on the lower and vertical surfaces of the cavity 19. Therefore, a wide contact area between the ground electrode and the shield part is ensured, whereby electrical reliability therebetween can be obtained.

After the substrate 11 or 11′ (hereinafter, referred to as “11”) is prepared by the method of manufacturing the substrate according to the above-described exemplary embodiments, the electronic components 16 are mounted on a surface of the substrate 11 in operation S11 as shown in FIG. 4B. At this time, the electronic components 16 are repeatedly mounted in all the individual semiconductor package areas A. That is, each of the individual semiconductor package areas A may have the same type and same number of the electronic components 16 mounted therein.

Next, as shown in FIG. 4C, the mold part 14 is formed on the surface of the substrate 11 to seal the electronic components 16 in operation S12. The mold part 14 according to this embodiment is integrally formed to seal all the individual semiconductor package areas A on the strip substrate 11. However, the mold part 14 may be formed to seal each of the individual semiconductor package areas A individually according to necessity.

Then, as shown in FIG. 4D, the substrate 11 having the mold part 14 formed thereon is cut along the boundary C to be divided into the plurality of individual semiconductor packages 10 in operation S13.

The cutting process in operation S13 may be performed by a full cut process. The full cut process is a process in which the upper and lower surfaces of a structure are cut at a time by the use of a blade 50. As compared with a process in which part of the structure (e.g., the substrate having the mold part formed thereon) is firstly cut and the remaining part is secondly cut, this full cut process may allow the individual semiconductor packages 10 to have smooth cut surfaces and a uniform size.

Here, when the individual semiconductor packages 10 are formed by the cutting process in operation S13, the cavities 19 formed inside the strip substrate 11 are exposed to the cut surfaces of the substrate 11, i.e., the side surfaces of the substrate 11 of the individual semiconductor packages 10. With the exposure of the cavity 19, the ground electrode 13 formed inside the cavity 19 is also exposed.

Meanwhile, in order to facilitate the formation of the shield part 15 on the individual semiconductor packages 10 after the operation S13, the lower part of the substrate 11 of the individual semiconductor packages 10 may be fixed.

Lastly, as shown in FIG. 4E, the shield part 15 is formed on the outer surface of the mold part 14 in operation S14. The shield part 15 is formed on the upper and side surfaces of the mold part 14 so as to be attached and integrated with the mold part 14.

Also, the shield part 15 is formed to extend up to the side surfaces of the substrate 11. At this time, the shield part 15 is also formed in the inside of the cavity 19. In the present embodiment, the shield part 15 is electrically connected to the ground electrode 13 formed in the cavity 19.

Such a shield part 15 may be realized as a metallic thin film. In this case, the metallic thin film may be formed by spray coating or conformal coating. The spray coating is not only suitable for the formation of a uniform coating film, but also is advantageous in a reduction of costs, excellent in terms of productivity, and environmental-friendly as compared with other film formation processes such as electroplating, electroless plating, or sputtering.

Meanwhile, the method of manufacturing the semiconductor package according to the present invention may include applying plasma processing to the shield part 15 after the formation of the shield part 15, in order to improve abrasion resistance and corrosion resistance on the surface of the shield part 15.

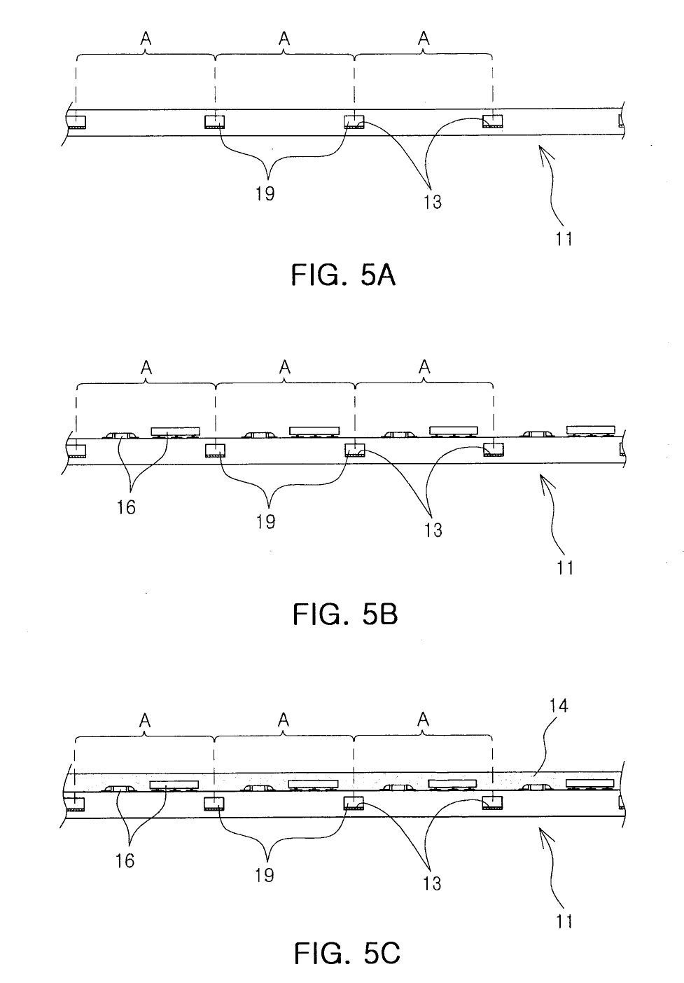

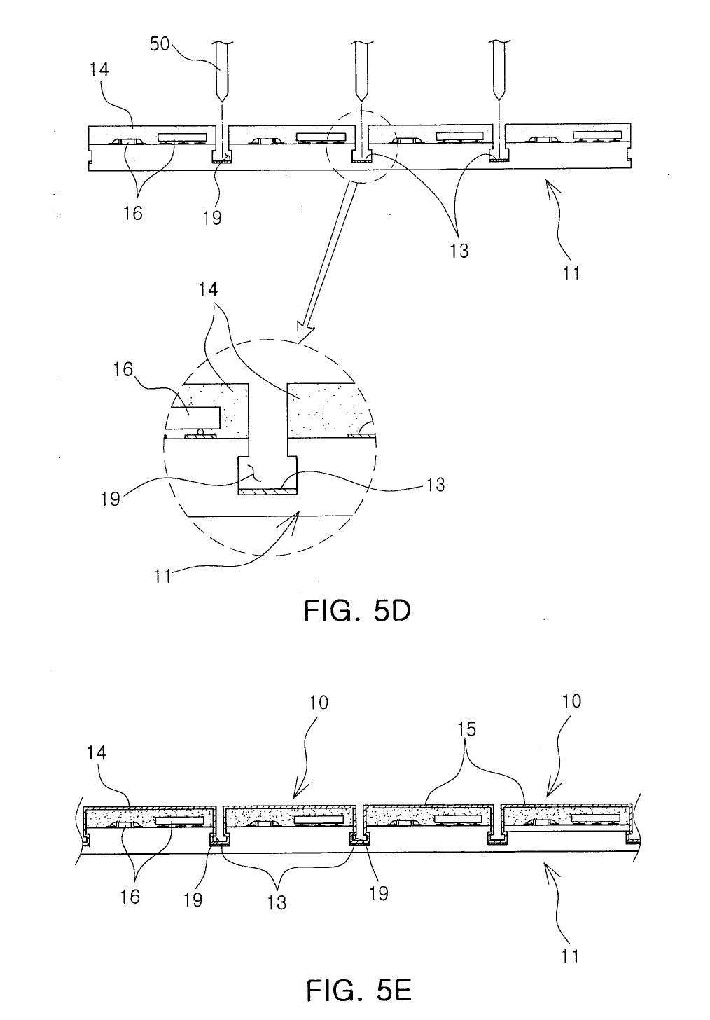

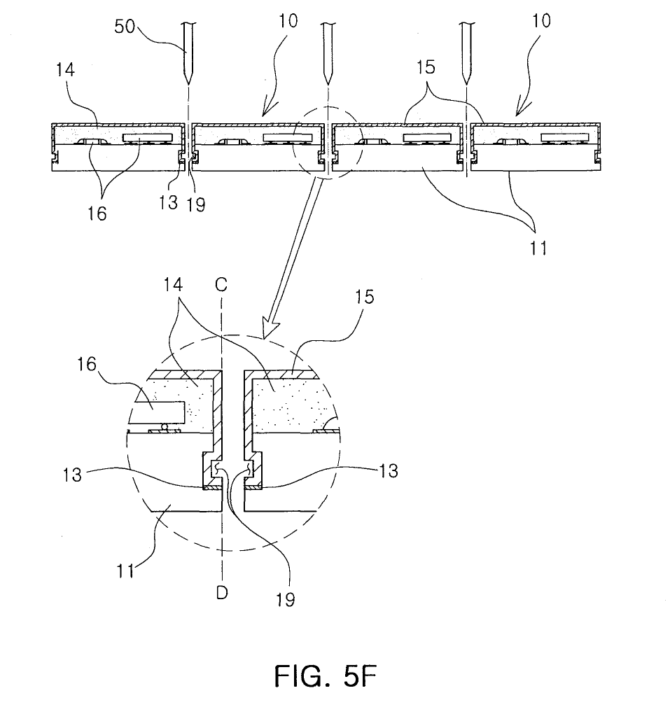

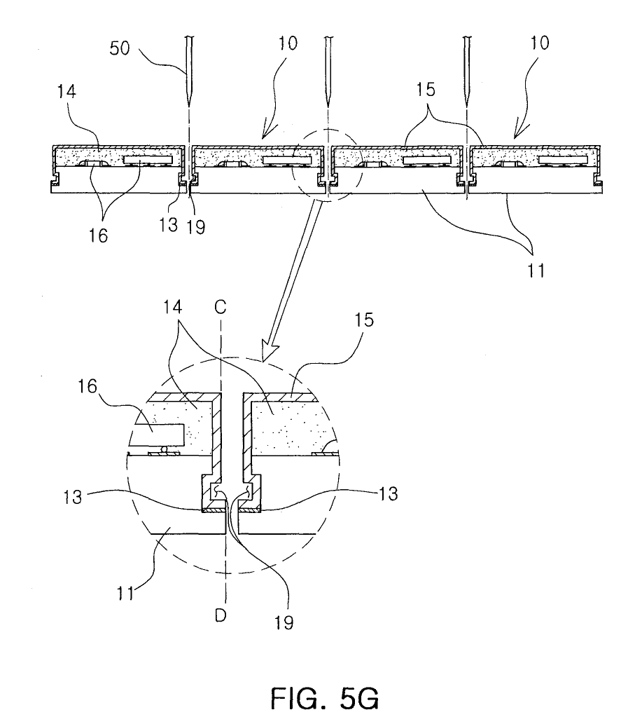

FIGS. 5A through 5G are cross-sectional views illustrating a method of manufacturing a semiconductor package according to another exemplary embodiment of the invention. The method of manufacturing the semiconductor package according to this embodiment is similar to the method thereof according to the aforementioned embodiment, with the exception of the difference in the cutting of the substrate having the mold part formed thereon into the individual semiconductor packages. Accordingly, a detailed description of the same processes will be omitted, and a detailed description of a different process, i.e., the cutting of the substrate having the mold part formed thereon into the individual semiconductor packages will be provided below.

Operations S20 to S22 described in FIGS. 5A through 5C are performed in the same manner as operations S10 to S12 described in FIGS. 4A through 4C of the aforementioned embodiment. Accordingly, a detailed description thereof is omitted.

With reference to FIG. 5D, the substrate 11 having the mold part 14 is subjected to a first cutting process in operation S23. This first cutting process is performed along the boundary between the individual semiconductor package areas A up to a position where the cavity 19 is formed by the use of the blade 50. That is, in operation S23, part of the substrate 11 is cut by a half-dicing process. The substrate 11 is cut only up to the position where the cavity 19 is formed. Accordingly, the part of the substrate 11 under the cavity 19 is maintained to be continuous, rather than being cut.

Also, with the substrate 11 being cut up to the position where the cavity 19 is formed by the first cutting process in operation S23, the ground electrode 13 formed on the lower surface of the cavity 19 is exposed to the outside.

Subsequently, as shown in FIG. 5E, the shield part 15 is formed on the firstly cut substrate 11 in operation S24. As shown in FIG. 5E, the shield part 15 is entirely formed to cover the outer surface of the mold part 14 and the inside of the cavity 19 being exposed by the first cutting process. Accordingly, the shield part 15 is also formed on the ground electrode 13 within the cavity 19 so that the shield part 15 is electrically connected to the ground electrode 13.

Meanwhile, the shield part 15 according to the present embodiment is formed by spray coating. However, the invention is not limited thereto. Screen printing may also be used therefor.

When the shield part 15 is formed by screen printing, conductive paste is coated on the upper surface of the mold part 14 and also fills the groove formed by the first cutting process, and then a hardening process is performed thereupon, thereby forming the shield part 15.

However, the method of forming the shield part 15 is not limited thereto. Various methods such as sputtering, vapor deposition, electroplating, or electroless plating may be used therefor.

Lastly, as shown in FIG. 5F, the remaining part of the strip substrate 11 having the shield part 15 formed thereon is subjected to a second cutting process in operation S25 to thereby form the individual semiconductor packages 10. This second cutting process in operation S25 is performed to cut the upper and lower surfaces of the substrate 11 having the shield part 15 formed thereon at a time. In this manner, the strip substrate 11 is completely divided into the individual semiconductor packages 10.

In the case of the embodiment of FIG. 5F, a vertical outer surface C on which the shield part 15 is formed and a cut surface D of the substrate 11 are positioned on almost the same plane. This semiconductor package 10 may be formed by cutting the substrate 11 along the vertical outer surface C of the shield part 15 in the second cutting process. In the case that the cut surface D of the substrate 11 and the vertical outer surface C of the shield part 15 are positioned on almost the same plane, the size of the semiconductor package 10 can be minimized.

Meanwhile, FIG. 5G illustrates an exemplary embodiment different from that of FIG. 5F. In the case of the embodiment of FIG. 5G, the vertical outer surface C of the shield part 15 and the cut surface D of the substrate 11 are positioned on different planes. This structure may be formed by cutting the substrate 11 using a thinner blade in the second cutting process than the blade used in the first cutting process. In the case that the semiconductor package 10 has the structure as shown in FIG. 5G, electrical connection is made in a wider contact area between the ground electrode 13 and the shield part 15, whereby electrical reliability can be achieved.

As set forth above, in a semiconductor package and a manufacturing method thereof according to exemplary embodiments of the invention, a shield part is formed on the outer surface of a mold part having insulating properties and is connected to a ground electrode exposed to the side surface of the semiconductor package, so there is no need to provide a separate structure for the grounding of the shield part. Thus, the semiconductor package can be minimized and obtain a superior effect in shielding electromagnetic waves.

In a semiconductor package and a manufacturing method thereof according to exemplary embodiments of the invention, a shield part and a ground electrode are electrically connected by the use of a cavity formed inside a substrate. In this manner, since a wider contact area between the shield part and the ground electrode is obtained, contact strength therebetween is increased to thereby ensure electrical reliability. Furthermore, since the semiconductor package may be manufactured without forming a separate ground electrode on the upper part of the substrate, the manufacturing of the semiconductor package can be facilitated.

Meanwhile, the semiconductor package and the manufacturing method thereof according to the present invention is not limited to the above-described exemplary embodiments, but can be realized in various embodiments. Also, the semiconductor package is taken as an example in the above-described exemplary embodiments, but any device for shielding electromagnetic waves may be applied thereto.

While the present invention has been shown and described in connection with the exemplary embodiments, it will be apparent to those skilled in the art that modifications and variations can be made without departing from the spirit and scope of the invention as defined by the appended claims.

What is claimed is:

1. A semiconductor package comprising:
a substrate having at least one cavity formed in a side surface thereof and an electrode provided within the cavity;
at least one electronic component mounted on a surface of the substrate;
a mold part sealing the electronic component and having insulating properties; and
a shield part attached to the mold part to cover an outer surface of the mold part, electrically connected to the electrode provided within the cavity, and having conductive properties.

2. The semiconductor package of claim 1, wherein the shield part is provided to extend along the side surface of the substrate.

3. The semiconductor package of claim 1, wherein the electrode is provided on at least one surface of the cavity.

4. The semiconductor package of claim 1, wherein the electrode is formed by filling the cavity with a conductive material.

5. The semiconductor package of claim 1, wherein the cavity is elongated in the side surface of the substrate in a lengthwise direction.

6. A method of manufacturing a semiconductor package, the method comprising:
preparing a substrate having at least one cavity and an electrode provided within the cavity;
mounting an electronic component on an upper surface of the substrate;
forming a mold part having insulating properties to seal the electronic component; and
forming a shield part on an outer surface of the mold part, the shield part being electrically connected to the electrode provided within the cavity and having conductive properties.

7. The method of claim 6, wherein the substrate has the cavity formed in at least one side surface thereof.

8. The method of claim 6, wherein the shield part is formed to extend up to the side surface of the substrate.

9. The method of claim 6, wherein the substrate is shaped as a strip including a plurality of individual semiconductor package areas.

10. The method of claim 9, wherein the substrate has the cavity formed in the inside thereof along a boundary dividing the individual semiconductor package areas.

11. The method of claim 10, wherein the electronic component is mounted on each of the individual semiconductor package areas.

12. The method of claim 11, wherein the mold part is integrally formed to seal all the individual semiconductor package areas.

13. The method of claim 12, wherein the forming of the shield part comprises:
dividing the substrate having the mold part formed thereon into individual semiconductor packages by cutting the substrate according to the individual semiconductor package areas; and
forming the shield part on each of the individual semiconductor packages.

14. The method of claim 13, wherein the dividing of the substrate into the individual semiconductor packages causes the cavity to be exposed through the side surface of the substrate being cut.

15. The method of claim 13, wherein the forming of the shield part on each of the individual semiconductor packages is performed by spray coating.

16. The method of claim 12, wherein the forming of the shield part comprises:
a first cutting process cutting the substrate having the mold part formed thereon according to the individual semiconductor package areas only up to a position where the cavity is formed;
forming the shield part on the substrate subjected to the first cutting process; and
a second cutting process completely cutting the substrate having the shield formed thereon.

17. The method of claim 16, wherein the forming of the shield part on the substrate subjected to the first cutting process comprises forming the shield part on the outer surface of the mold part and in the cavity exposed through the first cutting process.

18. The method of claim 16, wherein the second cutting process is performed to cause a cut surface of the substrate and a vertical outer surface of the shield part to be positioned on different planes.

19. The method of claim 16, wherein the forming of the shield part on the substrate subjected to the first cutting process is performed by any one of spray coating or screen printing.
